(19) United States
(12) Patent Application Publication
(10) Pub. No.: US 2017/0084800 A1
(43) Pub. Date: Mar. 23, 2017

(54) LIGHT EMITTING DEVICE PACKAGE STRUCTURE AND MANUFACTURING METHOD THEREOF

(71) Applicant: Genesis Photonics Inc., Tainan City (TW)

(72) Inventors: Cheng-Wei Hung, Tainan City (TW); Po-Tsun Kuo, Chiayi City (TW); Long-Chi Du, Tainan City (TW); Jui-Fu Chang, Tainan City (TW); Yu-Feng Lin, Tainan City (TW)

(73) Assignee: Genesis Photonics Inc., Tainan City (TW)

(21) Appl. No.: 15/268,652

(22) Filed: Sep. 19, 2016

Related U.S. Application Data
(60) Provisional application No. 62/220,249, filed on Sep. 18, 2015.
(60) Provisional application No. 62/236,150, filed on Oct. 2, 2015.
(60) Provisional application No. 62/245,247, filed on Oct. 22, 2015.
(60) Provisional application No. 62/262,876, filed on Dec. 3, 2015.

(30) Foreign Application Priority Data
Jan. 8, 2016 (TW) 105100508

(51) Int. Cl. H01L 33/54; H01L 33/62; H01L 33/46; H01L 33/50

(52) U.S. Cl. CPC H01L 33/54; H01L 33/502; H01L 33/62; H01L 33/46

(57) ABSTRACT

A light emitting device package structure includes at least one light emitting device, a wavelength conversion adhesive layer, and a protection element. The light emitting device has an upper surface, a lower surface opposite to the upper surface, and a side surface connecting the upper surface and the lower surface. The wavelength conversion adhesive layer is disposed on the upper surface of the light emitting device and has a first edge and a second edge opposite to each other. The protection element encapsulates the side surface of the light emitting device and the second edge of the wavelength conversion adhesive layer and exposes the lower surface of the light emitting device. A third edge of the protection element is aligned with the first edge of the wavelength conversion adhesive layer.

### CROSS-REFERENCE TO RELATED APPLICATION

This application claims the priority benefits of U.S. provisional application Ser. No. 62/220,249, filed on Sep. 18, 2015, U.S. provisional application Ser. No. 62/236,150, filed on Oct. 2, 2015, U.S. provisional application Ser. No. 62/245,247, filed on Oct. 22, 2015, U.S. provisional application Ser. No. 62/262,876, filed on Dec. 3, 2015, and Taiwan application serial no. 105100508, filed on Jan. 8, 2016. The entirety of the above-mentioned patent application is hereby incorporated by reference herein and made a part of this specification.

### FIELD OF DISCLOSURE

The disclosure relates to a light emitting device package structure and a manufacturing method thereof. More particularly, the disclosure relates to a light emitting device package structure using a light emitting diode (LED) and a manufacturing method thereof.

### DESCRIPTION OF RELATED ART

Since the light emitting diode (LED) has the advantages of compactness and long service time, it is more and more common to employ the LED as a light source. The LED is a light source with a directive property, and thus the brightness of a direct incidence area in front of the LED light source is usually higher than the brightness of a non-direct incidence area. Due to its directive property, the LED is often applied in a light source apparatus that requires the high brightness in specific areas, which poses a limitation to the application range of the LED.

### SUMMARY OF THE DISCLOSURE

The disclosure is directed to a light emitting device package structure that achieves favorable lateral light exiting effects.

The disclosure is also directed to a method for manufacturing the aforesaid light emitting device package structure.

In an embodiment of the disclosure, a light emitting device package structure that includes at least one light emitting device, a wavelength conversion layer, and a protection element. The at least one light emitting device has an upper surface, a lower surface opposite to the upper surface, and a side surface connecting the upper surface and the lower surface. The wavelength conversion layer is disposed on the upper surface of the at least one light emitting device, and the wavelength conversion layer has a first surface and a second surface opposite to each other. The protection element encapsulates the side surface of the at least one light emitting device and the second surface of the wavelength conversion layer and exposes the lower surface of the at least one light emitting device. A third surface of the protection element is aligned with the first surface of the wavelength conversion layer.

According to an embodiment of the disclosure, the wavelength conversion layer includes a low concentration e layer and a high concentration layer. The upper surface of the at least one light emitting device is in contact with the high concentration layer. The low concentration layer has the first side surface and the second side surface. The high concentration layer has a fourth side surface and a fifth side surface opposite to each other. The first side surface of the low concentration layer is extended out of the fourth side surface of the high concentration layer, and the fifth side surface of the high concentration layer is aligned with the second side surface of the low concentration layer.

According to an embodiment of the disclosure, the protection element includes a first protection element and a second protection element. The low concentration layer has a first surface and a second surface opposite to each other. The high concentration layer is disposed on the first surface of the low concentration layer. The second protection element encapsulates the side surface of the at least one light emitting device, the second side surface of the low concentration layer, and the fourth side surface and the fifth side surface of the high concentration layer. A top surface of the second protection element is aligned with the second surface of the low concentration layer. The first protection element covers the second surface of the low concentration layer and the top surface of the second protection element.

According to an embodiment of the disclosure, a length of the first side surface of the wavelength conversion layer is greater than a length of the second side surface of the wavelength conversion layer.

According to an embodiment of the disclosure, the wavelength conversion layer has a die bonding stage and an inclined bottom opposite to the die bonding stage. The at least one light emitting device is located on the die bonding stage, and an acute angle is formed between the inclined bottom and an extension direction of the first side surface.

According to an embodiment of the disclosure, the protection element includes a first protection element and a second protection element. The first protection element encapsulates the wavelength conversion layer. The second protection element encapsulates the side surface of the at least one light emitting device and covers the first protection element.

According to an embodiment of the disclosure, the light emitting device package structure further includes a distributed Bragg reflective layer disposed on a side surface of the first protection element relatively away from the wavelength conversion layer.

According to an embodiment of the disclosure, the light emitting device package structure further includes a reflective protection layer disposed on the distributed Bragg reflective layer, and the distributed Bragg reflective layer is located between the first protection element and the reflective protection layer.

According to an embodiment of the disclosure, the light emitting device package structure further includes a distributed Bragg reflective layer. The distributed Bragg reflective layer is disposed on the inclined bottom of the wavelength conversion layer and covers the inclined bottom.

According to an embodiment of the disclosure, the light emitting device package structure further includes a distributed Bragg reflective layer disposed on the upper surface of the at least one light emitting device, and the distributed Bragg reflective layer completely covers or partially covers the upper surface of the at least one light emitting device.

According to an embodiment of the disclosure, the light emitting device package structure further includes a die bonding layer disposed between the side surface of the at least one light emitting device and the protection element.

According to an embodiment of the disclosure, the number of the at least one light emitting device is plural. The light emitting devices are spaced from one another, and every two adjacent light emitting devices of the light emitting devices expose a portion of the wavelength conversion layer.

In an embodiment of the disclosure, a light emitting device package structure that includes at least one light emitting device, a wavelength conversion layer, and a protection element. The at least one light emitting device has an upper surface, a lower surface, and a side surface connecting the upper surface and the lower surface. The wavelength conversion layer is disposed on the upper surface of the at least one light emitting device, and the wavelength conversion layer has a first side surface, a second side surface opposite to the first side surface, and a top surface connecting the first side surface and the second side surface. The protection element encapsulates the first side surface of the at least one light emitting device, the second side surface of the wavelength conversion adhesive layer, and the top surface of the wavelength conversion adhesive layer. A third side surface of the protection element is aligned with the first side surface of the wavelength conversion layer.

According to an embodiment of the disclosure, a length of the first side surface of the wavelength conversion layer is greater than a length of the second side surface of the wavelength conversion layer.

According to an embodiment of the disclosure, the wavelength conversion layer has a die bonding stage opposite to the top surface of the wavelength conversion layer, and the at least one light emitting device is located on the die bonding stage.

According to an embodiment of the disclosure, the protection element includes a first protection element and a second protection element. The first protection element encapsulates the side surface of the at least one light emitting device, and the second protection element encapsulates the wavelength conversion layer but exposes the first side surface of the wavelength conversion layer.

In an embodiment of the disclosure, a light emitting device package structure that includes at least one light emitting device, a first protection element, a wavelength conversion layer, and a second protection element. The at least one light emitting device has an upper surface, a lower surface, and a side surface connecting the upper surface and the lower surface. The first protection element encapsulates the side surface of the at least one light emitting device. The wavelength conversion layer is disposed on the upper surface of the at least one light emitting device and a portion of the first protection element, and the wavelength conversion layer has a first side surface, a second side surface opposite to the first side surface, and a top surface connecting the first side surface and the second side surface. The second protection element is disposed on a portion of the first protection element and at least encapsulates the second side surface and the top surface of the wavelength conversion layer. The at least one light emitting device has a light exiting plane, and the light exiting plane includes a portion of a third side surface of the first protection element, the first side surface of the wavelength conversion layer, and a portion of a fourth side surface of the second protection element.

According to an embodiment of the disclosure, a length of the first side surface of the wavelength conversion layer is greater than a length of the second side surface of the wavelength conversion layer.

According to an embodiment of the disclosure, the wavelength conversion layer has a die bonding stage opposite to the top surface of the wavelength conversion layer, and the at least one light emitting device is located on the die bonding stage.

According to an embodiment of the disclosure, the first protection element further includes a reflective curved surface that surrounds the side surface of the at least one light emitting device and is in contact with the side surface.

In an embodiment of the disclosure, a manufacturing method of a light emitting device package structure includes following steps. A wavelength conversion layer that includes a low concentration layer and a high concentration layer is provided. A first protection element is formed on the low concentration layer of the wavelength conversion layer. A cutting process is performed to form a plurality of first recesses and a plurality of second recesses. The first recesses expose the low concentration layer, the second recesses respectively communicate with the first recesses and expose a portion of the first protection element, and a diameter of each of the second recesses is smaller than a diameter of a corresponding first recess of the first recesses. Plural light emitting devices are placed on the wavelength conversion layer. Each of the light emitting devices has an upper surface, a lower surface opposite to the upper surface, and a side surface connecting the upper surface and the lower surface, and the upper surfaces of the light emitting devices are in contact with the high concentration layer. A second protection element is formed on the first protection element and encapsulates the side surfaces of the light emitting devices and the wavelength conversion layer, and the first recesses and the second recesses are filled with the second protection element. Another cutting process is performed to cut the second protection element and the first protection element along the second recesses, so as to form a plurality of separated light emitting device package structures. Here, a first side surface of the first protection element of each of the light emitting device package structures, a second side surface of the second protection element of each of the light emitting device package structures, and a third side surface of the low concentration layer of the wavelength conversion adhesive layer are aligned with one another.

According to an embodiment of the disclosure, the step of performing the cutting process includes: performing a first cutting process to cut the high concentration layer and then the low concentration layer, so as to form the first recesses; performing a second cutting process to cut through the low concentration layer along the first recesses, so as to form the second recesses.

According to an embodiment of the disclosure, the manufacturing method further includes: forming a die bonding layer on the side surfaces of the light emitting devices after placing the light emitting devices on the wavelength conversion layer and before forming the second protection element.

According to an embodiment of the disclosure, the manufacturing method further includes: providing a double-sided adhesive film after forming the first protection element and before performing the cutting process. The first protection element is located between the double-sided adhesive film and the low concentration layer.

According to an embodiment of the disclosure, reflectivity of the first protection element and reflectivity of the second protection element are at least greater than 90%.

In an embodiment of the disclosure, a manufacturing method of a light emitting device package structure includes following steps. A first protection element that has a plurality of first recesses is provided, and each of the first recesses has an inclined bottom surface. A wavelength conversion material is provided to fill the first recesses and define a plurality of wavelength conversion layers. Each of the wavelength conversion layers has a die bonding stage, a first side surface, and a second side surface opposite to the first side surface, and a length of the first side surface is greater than a length of the second side surface. Plural light emitting devices are placed on the wavelength conversion layer. Each of the light emitting devices has an upper surface, a lower surface opposite to the upper surface, and a side surface connecting the upper surface and the lower surface, and the upper surfaces of the light emitting devices are in contact with the die bonding stages. A second protection element is formed to encapsulate the side surfaces of the light emitting devices and covers the first protection element and the wavelength conversion e layers. A cutting process is performed to cut the second protection element and the first protection element, such that the first side surface of each of the wavelength conversion layers, a third side surface of the first protection element, and a fourth side surface of the second protection element are aligned with one another to form a plurality of light emitting device package structures.

According to an embodiment of the disclosure, the manufacturing method further includes: forming a plurality of second recesses extending from the second protection element to the first protection element after forming the second protection element and before performing the cutting process. Here, the second recesses respectively expose the first side surfaces of the wavelength conversion layers, each of the second recesses has an inclined light absorbing surface and a vertical plane, the inclined light absorbing surfaces face the first edges of the wavelength conversion layers, and the first side surfaces are respectively aligned with the vertical planes.

According to an embodiment of the disclosure, each of the first recesses further has a vertical sidewall connected to the inclined bottom surface, and an acute angle is formed between an extension direction of the vertical sidewall and the inclined bottom surface.

According to an embodiment of the disclosure, the manufacturing method further includes: forming a die bonding layer on the side surfaces of the light emitting devices after placing the light emitting devices on the wavelength conversion layers and before forming the second protection element.

According to an embodiment of the disclosure, a height difference exists between each of the die bonding stages and a surface of the first protection element, and a ratio of the height difference to a thickness of the first protection element is at least 0.2.

According to an embodiment of the disclosure, reflectivity of the first protection element and reflectivity of the second protection element are at least greater than 90%.

According to an embodiment of the disclosure, the manufacturing method further includes: forming a distributed Bragg reflective layer on a side surface of the first protection element relatively away from the wavelength conversion e layers after forming the second protection element and before performing the cutting process.

According to an embodiment of the disclosure, the manufacturing method further includes: forming a reflective protection layer on the distributed Bragg reflective layer after forming the distributed Bragg reflective layer. The distributed Bragg reflective layer is located between the first protection element and the reflective protection layer.

According to an embodiment of the disclosure, the manufacturing method further includes: forming a plurality of distributed Bragg reflective layers in the first recesses after providing the first protection element and before providing the wavelength conversion material to fill the first recesses.

According to an embodiment of the disclosure, the manufacturing method further includes: forming a distributed Bragg reflective layer on the die bonding stages of the wavelength conversion layers after providing the wavelength conversion material to fill the first recesses and before placing the light emitting devices respectively on the wavelength conversion e layers.

In view of the above, the protection element of the light emitting device package structure encapsulates the side surface of the light emitting device and one edge of the wavelength conversion layer, and the other edge of the wavelength conversion layer is aligned with an edge of the protection element. Thanks to the design of the protection element, the light emitted from the light emitting device can render reflective effects, and the wavelength conversion layer guides the light emitted from the light emitting device to exit from the lateral instead of exiting from the front. Thereby, the t emitting device package structure not only achieves favorable lateral light exiting effects but also has large light emitting area and favorable light emitting uniformity.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1F are schematic cross-sectional diagrams illustrating a manufacturing method of a light emitting device package structure according to an embodiment of the disclosure.

FIG. 2 is a schematic cross-sectional diagram illustrating a light emitting device package structure according to an embodiment of the disclosure.

FIG. 3A to FIG. 3G are schematic cross-sectional diagrams illustrating a manufacturing method of a light emitting device package structure according to another embodiment of the disclosure.

FIG. 4A is a schematic three-dimensional diagram illustrating the light emitting device package structure depicted in FIG. 3G.

FIG. 4B is a schematic cross-sectional diagram taken along the line Y-Y depicted in FIG. 4A.

FIG. 5A to FIG. 5E are schematic cross-sectional diagrams illustrating a light emitting device package structure according to several embodiments of the disclosure.

### DETAILED DESCRIPTION OF DISCLOSED EMBODIMENTS

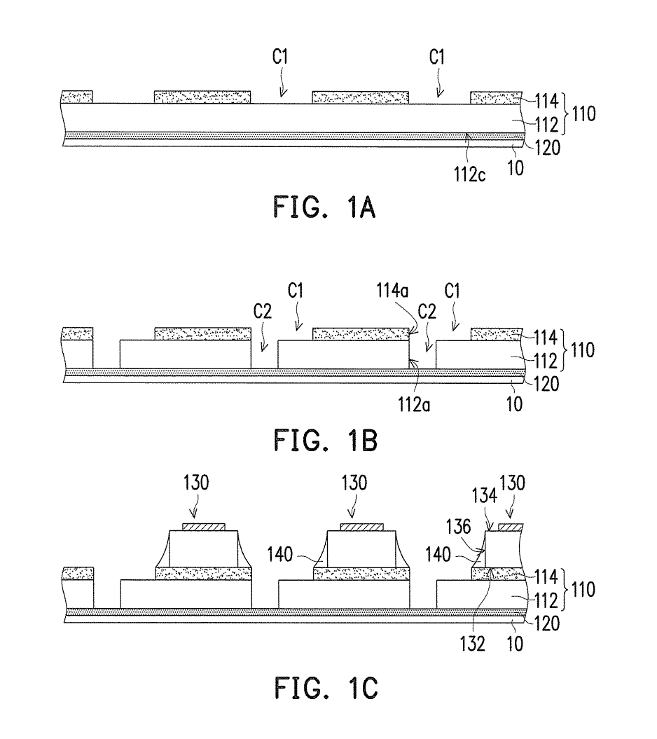

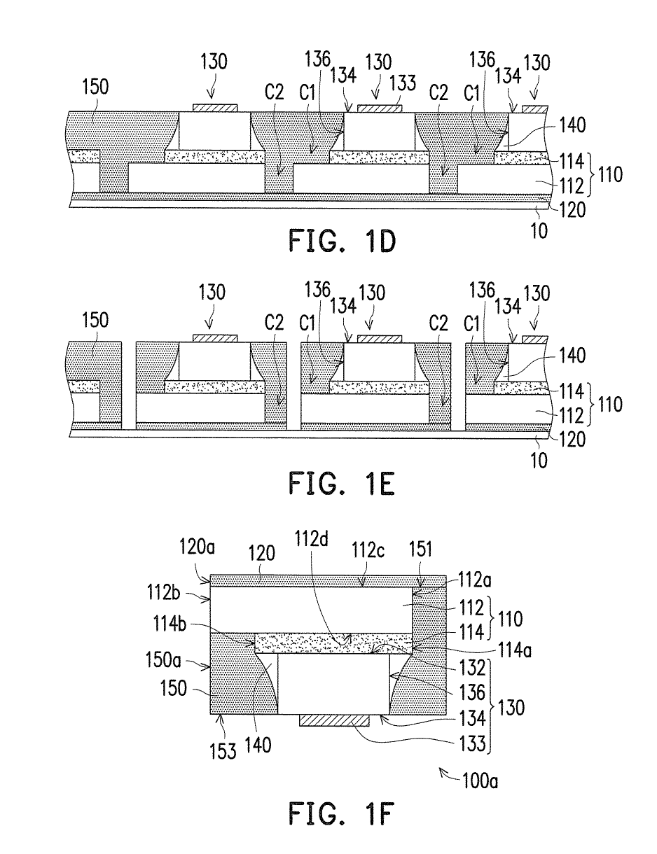

FIG. 1A to FIG. 1F are schematic cross-sectional diagrams illustrating a manufacturing method of a light emitting device package structure according to an embodiment of the disclosure. Note that FIG. 1A to FIG. 1F are depicted along one direction (e.g., an X-X direction), and hence each of the resultant light emitting device package structures has one light emitting device; however, in another direction (e.g., a Y-Y direction), each of the light emitting device package structures may have a plurality of light emitting devices.

With reference to FIG. 1A, according to the manufacturing method of the light emitting device package structure provided herein, a wavelength conversion layer 110 is provided, and the wavelength conversion adhesive layer 110 includes a low concentration layer 112 and a high concentration e layer 114. The step of forming the wavelength conversion layer 110 includes: forming a wavelength conversion layer (not shown) constituted by fluorescent powder (not shown) and silica gel (not shown) on a releasing film (not shown) through dispensing, and the wavelength conversion layer is placed for a period of time (e.g., 24 hours). Due to the difference in the density of the fluorescent powder and that of the silica gel, the wavelength conversion layer 110 having the low concentration layer 112 and the high concentration layer 114 that are separated from each other is formed. Here, the high concentration layer 114 is deposited below the low concentration layer 112, the color of the high concentration layer 114 is yellow, and the low concentration adhesive layer 112 is transparent, for instance. However, the disclosure is not limited thereto. In the present embodiment, a thickness of the low concentration layer 112 is greater than a thickness of the high concentration layer 114, so as to increase the possibility of mixing light successfully. In an embodiment, a ratio of the thickness of the low concentration layer 112 to the thickness of the high concentration layer 114 may be between 1 and 100.

As shown in FIG. 1A, a first protection element 120 is formed on the low concentration layer 112 of the wavelength conversion layer 110, and the low concentration layer 112 is located between the high concentration layer 114 and the first protection element 120. Here, the first protection element 120 completely covers a surface 112c of the low concentration layer 112. Reflectivity of the first protection element 120 is at least greater than 90%, and the first protection element 120 is a layer of white glue or a metal plating layer, for instance. The releasing film is then removed, the wavelength conversion layer 110 and the first protection element 120 are turned upside down, and a double-sided adhesive film 10 is provided. The first protection element 120 is fixed onto the double-sided adhesive film 10 and located between the double-sided adhesive film 10 and the low concentration layer 112.

With reference to FIG. 1A and FIG. 1B, a cutting process is performed to form a plurality of first recesses C1 and a plurality of second recesses C2. The first recesses C1 expose the low concentration layer 112, and the second recesses C2 respectively overlap with the first recesses C1 and expose a portion of the first protection element 120. Here, a diameter of each of the second recesses C2 is smaller than a diameter of one of the corresponding first recesses C1.

Particularly, the step of performing the cutting process includes: performing a first cutting process to cut the high concentration layer 114, so as to form the first recesses C1 (as shown in FIG. 1A). Here, the first recesses C1 penetrate the high concentration layer 114. With reference to FIG. 1B, a second cutting process is performed to cut through the low concentration layer 112 along the first recesses C1, so as to form the second recesses C2. Here, the second recesses C2 penetrate the low concentration layer 112. Since the first recesses C1 and the second recesses C2 are formed, the surface area of the low concentration layer 112 is greater than the surface area of the high concentration adhesive layer 114, such that the area of the light exiting surface can be effectively increased. As shown in FIG. 1B, the diameter of the first recesses C1 is greater than the diameter of the second recesses C2, and a side surface 114a of the high concentration layer 114 is aligned with a side surface 112a of the low concentration layer 112.

With reference to FIG. 1C, plural light emitting devices 130 are placed on the wavelength conversion layer 110. Each of the light emitting devices 130 has an upper surface 132, a lower surface 134 opposite to the upper surface 132, and a side surface 136 connecting the upper surface 132 and the lower surface 134, and the upper surfaces 132 of the light emitting devices 130 are in contact with the high concentration layer 114, so as to enhance the light extraction rate and improve the light shape. Each of the light emitting devices 130 is an LED chip with the light emitting wavelength from 315 nm to 780 nm, and the LED chip includes but is not limited to an ultraviolet LED chip, a blue LED chip, a green LED chip, a yellow LED chip, an orange LED chip, or a red LED chip.

With reference to FIG. 1C, a die bonding layer 140 is formed on the side surfaces 136 of the light emitting devices 130. As shown in FIG. 1C, the thickness of the die bonding layer 140 increases from the lower surface 134 to the upper surface 132 of each light emitting device 130, and the die bonding layer 140 has a concave surface relative to the side surface 136 of each light emitting device 130. However, the disclosure is not limited thereto. In other embodiments that are not shown, the amount of the material applied for forming the die bonding layer can be controlled, such that the die bonding layer may have a convex surface or an inclined surface relative to the side surface of the light emitting device. In addition, the die bonding layer 140 is configured not only to fix the location of the light emitting devices 130 but also to enhance the lateral light exiting effects of the light emitting devices 130.

With reference to FIG. 1D, a second protection element 150 is formed on the first protection element 120 and encapsulates the side surfaces 136 of the light emitting devices 130 and the wavelength conversion layer 110, and the first recesses C1 and the second recesses C2 are filled with the second protection element 150. Here, the second protection element 150 completely encapsulates the light emitting devices 130 and the wavelength conversion layer 110 except for the lower surfaces 134 of the light emitting devices 130 and the electrodes 133 located on the lower surfaces 134. Reflectivity of the second protection element 150 may be the same as that of the first protection element 120, i.e., at least greater than 90%, and the second protection element 150 is a layer of white glue, for instance.

With reference to FIG. 1E and FIG. 1F, another cutting process is performed to cut the second protection element 150 and the first protection element 120 along the second recesses C2, so as to form a plurality of separated light emitting device package structures 100a. Here, a side surface 120a of the first protection element 120 of each of the light emitting device package structures 100a, a side surface 150a of the second protection element 150 of each of the light emitting device package structures 100a, and a side surface 112b of the low concentration layer 112 of the wavelength conversion adhesive layer 110 are aligned with one another. The double-sided adhesive film 10 is then removed, so as to completely form the light emitting device package structures 100a. For illustrative purposes, FIG. 1F schematically illustrates one light emitting device package structure 100a.

Structurally speaking, as shown in FIG. 1F, the light emitting device package structure 100a includes the light emitting device 130, the wavelength conversion layer 110, and a protection element. The light emitting device 130 has the upper surface 132, the lower surface 134 opposite to the upper surface 132, the side surface 136 connecting the upper surface 132 and the lower surface 134, and the electrode 133 located on the lower surface 134. The wavelength conversion layer 110 is disposed on the upper surface 132 of the light emitting device 130 and includes the low concentration layer 112 and the high concentration layer 114. The high concentration layer 114 is disposed on the surface 112d of the low concentration layer 112. The upper surface 132 of the light emitting device 130 is in contact with the high concentration layer 114, so as to enhance the light extraction rate and improve the light shape. In FIG. 1F, the side surface 112b of the low concentration layer 112 is extended out of the side surface 114b of the high concentration layer 114, and the side surface 114a of the high concentration layer 114 is aligned with the side surface 112a of the low concentration layer 112.

As shown in FIG. 1F, the reflectivity of the protection element is at least greater than 90%, and the protection element includes the first protection element 120 and the second protection element 150. To be specific, the second protection element 150 encapsulates the side surface 136 of the light emitting device 130, the side surface 112a of the low concentration layer 112, and the side surfaces 114a and 114b of the high concentration layer 114. A top surface 151 of the second protection element 150 is aligned with the surface 112c of the low concentration layer 112, and a bottom surface 153 of the second protection element 150 is aligned with the lower surface 134 of the light emitting device 130 and exposes the electrode 133. The first protection element 120 covers the surface 112c of the low concentration layer 112 and the top surface 151 of the second protection element 150. Note that the side surface 120a of the first protection element 120, the side surface 150a of the second protection element 150, and the side surface 112b of the low concentration layer 112 of the wavelength conversion layer 110 are substantially aligned with one another. Besides, the light emitting device package structure 100a further includes the die bonding layer 140 located between the side surface 136 of the light emitting device 130 and the second protection element 150, so as to secure the location of the light emitting device 130 as well as enhance the lateral light exiting effect of the light emitting device 130.

The second protection element 150 of the light emitting device package structure 100a encapsulates the side surface 136 of the light emitting device 130, the side surface 112a of the low concentration layer 112 of the wavelength conversion layer 110, and the side surfaces 114a and 114b of the high concentration layer 114 of the wavelength conversion layer 110, and the side surface 112b of the low concentration layer 112 of the wavelength conversion layer 110 is aligned with the side surface 120a of the first protection element 120 and the side surface 150a of the second protection element 150. Hence, the light emitted from the light emitting device 130 can render the reflective effects due to the design of the first protection element 120 and the second protection element 150, and the wavelength conversion layer 110 may guide the light emitted from the light emitting device 130 to exit from the lateral instead of exiting from the front. Thereby, the light emitting device package structure 100a not only achieves favorable lateral light exiting effects but also has large light emitting area and favorable light emitting uniformity.

It should be mentioned that reference numbers and some descriptions provided in the previous exemplary embodiment are also applied in the following exemplary embodiment. The same reference numbers represent the same or similar components in these exemplary embodiments, and repetitive descriptions are omitted.

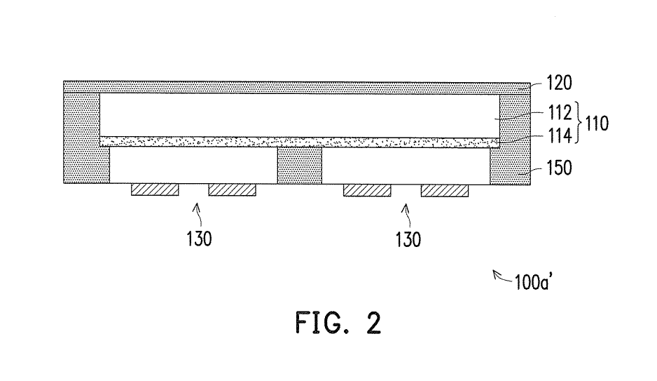

FIG. 2 is a schematic cross-sectional diagram illustrating a light emitting device package structure according to an embodiment of the disclosure. It should be mentioned that FIG. 2 is a schematic cross-sectional diagram taken along a direction (e.g., Y-Y) that is perpendicular to the direction shown in FIG. 1A to FIG. 1F. With reference to FIG. 2, the light emitting device package structure 100a′ provided in the present embodiment is similar to the light emitting device package structure 100a illustrated in FIG. 1F, and the difference therebetween is that the light emitting device package structure 100a′ provided in the present embodiment is embodied as a plurality of chip structures, i.e., the light emitting device package structure 100a′ has a plurality of light emitting devices 130 spaced from one another, and every two adjacent light emitting devices 130 expose a portion of the wavelength conversion layer 110. The light emitting devices 130 of the light emitting device package structure 100a′ are in contact with one wavelength conversion layer 110, i.e., the light emitting devices 130 have the same light exiting surface; accordingly, the light emitting device package structure 100a′ provided herein can have large light emitting area and favorable light emitting uniformity.

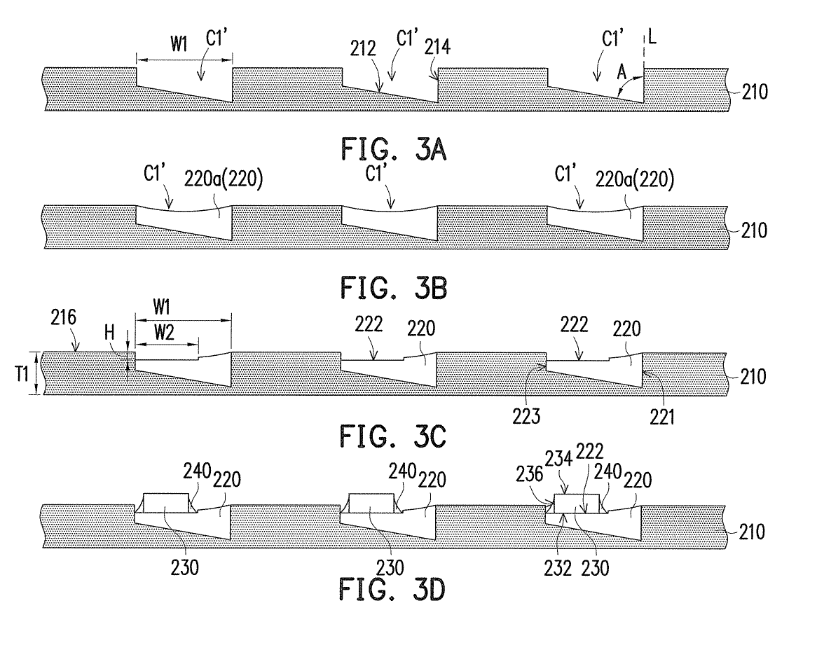

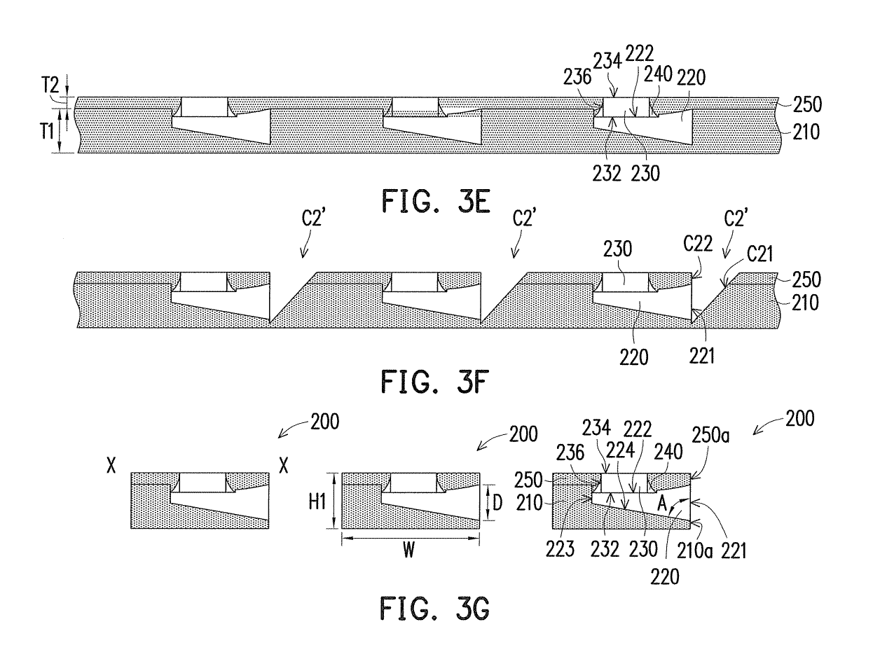

FIG. 3A to FIG. 3G are schematic cross-sectional diagrams illustrating a manufacturing method of a light emitting device package structure according to another embodiment of the disclosure. With reference to FIG. 3A, according to the manufacturing method of the light emitting device package structure provided herein, a first protection element 210 is provided, and the first protection element 210 includes a plurality of first recesses C1′. Each of the first recesses C1′ has an inclined bottom surface 212. The reflectivity of the first protection element 210 is at least greater than 90%, and the first protection element 210 is a layer of white glue or a metal plating layer, for instance. The first recesses C1′ are formed by performing the cutting process on one single inclined surface. Each first recess C1′ has a vertical sidewall 214 connected to the inclined bottom surface 212, and an acute angle A is formed between the vertical sidewall 214 and the inclined bottom surface 212. Preferably, the acute angle A is 80 degrees, which should however not be construed as a limitation to the disclosure. A width W1 of each first recess C1′ is 600 μm, for instance, which should however not be construed as a limitation to the disclosure.

With reference to FIG. 3B, a wavelength conversion material 220a is provided to fill the first recesses C1′ and define a plurality of wavelength conversion layers 220. Here, the first recesses C1′ are filled with the wavelength conversion material 220a through dispensing, and the wavelength conversion material 220a is heated and cured to form the wavelength conversion layers 220.

With reference to FIG. 3C, a die bonding stage 222 is defined on each of the wavelength conversion layers 220 through performing a scraping process by a scraper. Here, the width W1 of each first recess C1′ is 1.5 times the width W2 of the die bonding stage 222, i.e., the width W2 of the die bonding stage 222 is 400 μm, for instance, which should however not be construed as a limitation to the disclosure. A height H exists between each of the die bonding stages 222 and a surface 216 of the first protection element 210, and a ratio of the height difference H to a thickness T1 of the first protection element 210 is at least 0.2. For instance, if the thickness T1 of the first protection element 210 is 250 μm, the height H is 50 μm. However, the disclosure is not limited thereto. As shown in FIG. 3C, each of the wavelength conversion layers 220 has a side surface 221 and a side surface 223 opposite to each other, and an area of the side surface 221 is greater than an area of the side surface 223. That is, the shape of the cross-section of each wavelength conversion layer 220 is similar to a trapezoid.

With reference to FIG. 3D, plural light emitting devices 230 are respectively placed on the wavelength conversion layers 220. Each of the light emitting devices 230 has an upper surface 232, a lower surface 234 opposite to the upper surface 232, and a side surface 236 connecting the upper surface 232 and the lower surface 234, and the upper surfaces 232 of the light emitting devices 230 are respectively in contact with the die bonding stages 222, so as to enhance the light extraction rate and improve the light shape. Each of the light emitting devices 230 is an LED chip with the light emitting wavelength from 315 nm to 780 nm, and the LED chip includes but is not limited to an ultraviolet LED chip, a blue LED chip, a green LED chip, a yellow LED chip, an orange LED chip, or a red LED chip.

With reference to FIG. 3D, a die bonding layer 240 is formed on the side surface 236 of each light emitting device 230, and the die bonding layers 240 are in contact with the side surfaces 236 of the light emitting devices 230 and the die bonding stages 222. As shown in FIG. 3D, the thickness of the die bonding layer 240 increases from the lower surface 234 to the upper surface 232 of each light emitting device 230, and the die bonding layer 240 has a convex surface relative to the side surface 236 of the light emitting device 230. However, the disclosure is not limited thereto. In other embodiments that are not shown, the amount of the material applied for forming the die bonding layer can be controlled, such that the die bonding layer may have a concave surface or an inclined surface relative to the side surface of the light emitting device. This still falls within the scope of protection provided herein. In addition, the die bonding layer 240 is configured not only to fix the location of the light emitting devices 230 but also to enhance the lateral light exiting effects of the light emitting devices 230.

With reference to FIG. 3E, a second protection element 250 is formed to encapsulate the side surfaces 236 of the light emitting devices 230 and covers the first protection element 210 and the wavelength conversion layers 220. Here, the second protection element 250 exposes the lower surfaces 234 of the light emitting devices 230, and the first protection element 210 and the second protection element 250 can together seal the light emitting devices 230, the die bonding layers 240, and the wavelength conversion layers 220. Reflectivity of the second protection element 250 may be the same as that of the first protection element 210, i.e., at least greater than 90%, and the second protection element 250 is a layer of white glue, for instance. The thickness T2 of the second protection element 250 is 0.2 times the thickness T1 of the first protection element 210. For instance, the thickness T1 of the first protection element 210 may be 250 μm, and the thickness 12 of the second protection element 250 is 50 μm.

With reference to FIG. 3F, plural second recesses C2′ extending from the second protection element 250 to the first protection element 210 are formed, and the second recesses C2′ respectively expose the side surface 221 of the wavelength conversion layers 220. Particularly, each of the second recesses C2′ has an inclined light reflecting surface C21 and a vertical plane C22, the inclined light reflecting surfaces C21 face the side surface 221 of the wavelength conversion layers 220, and the side surface 221 are respectively aligned with the vertical planes C22. Here, the second recesses C2′ having the inclined light reflecting surfaces C21 and the vertical planes C22 are formed through cutting. The inclined light reflecting surfaces C21 are suitable for reflecting the lateral light emitted by the light emitting devices 230 and guided by the wavelength conversion layers 220, such that users can easily measure the brightness of the light emitted from the light emitting devices 230.

With reference to FIG. 3G, a cutting process is performed to cut the first protection element 210, such that the side surface 210a of the first protection element 210 is aligned with the side surface 250a of the second protection element 250 and the side surface 221 of each of the wavelength conversion layers 220. Plural light emitting device package structures 200 are then formed. So far, the manufacture of the light emitting device package structures 200 is completed.

Structurally speaking, as shown in FIG. 3G, each light emitting device package structure 200 includes the light emitting device 230, the wavelength conversion layer 220, and the protection element. Each light emitting device 230 has the upper surface 232, the lower surface 234 opposite to the upper surface 232, and the side surface 236 connecting the upper surface 232 and the lower surface 234. The wavelength conversion layer 220 is disposed on the upper surface 232 of the light emitting device 230, and an area of side surface 221 of the wavelength conversion layer 220 is greater than an area of the other side surface 223. The wavelength conversion layer 220 has the die bonding stage 222 and an inclined bottom 224 opposite to each other. The light emitting device 230 is located on the die bonding stage 222, and the acute angle A is formed between the inclined bottom 224 and the side surface 221. The protection element includes the first protection element 210 and the second protection element 250. The first protection element 210 encapsulates the inclined bottom 224 and the side surface 223 of the wavelength conversion layer 220, and the second protection element 250 encapsulates the side surface 236 of the light emitting device 230 and covers the first protection element 210 but exposes the lower surface 234 of the light emitting device 230. The side surface 210a of the first protection element 210, the side surface 250a of the second protection element 250, and the side surface 221 of the wavelength conversion layer 220 are substantially aligned with one another or coplanar.

In the present embodiment, each light emitting device package structure 200 has the protection element (i.e., the first and second protection elements 210 and 250), the side surface 221 of each wavelength conversion layer 220 is aligned with the side surface 210a of the first protection element 210 and the side surface 250a of the second protection element 250, and the area of the side surface 221 of each wavelength conversion layer 220 is greater than the area of the side surface 223 of the wavelength conversion layer 220. Hence, the light generated by the light emitting devices 230 in the present embodiment may be guided by the wavelength conversion layers 230, so as to generate the lateral light. Thereby, the light emitting device package structures 200 provided herein not only achieve favorable lateral light exiting effects but also has large light emitting area.

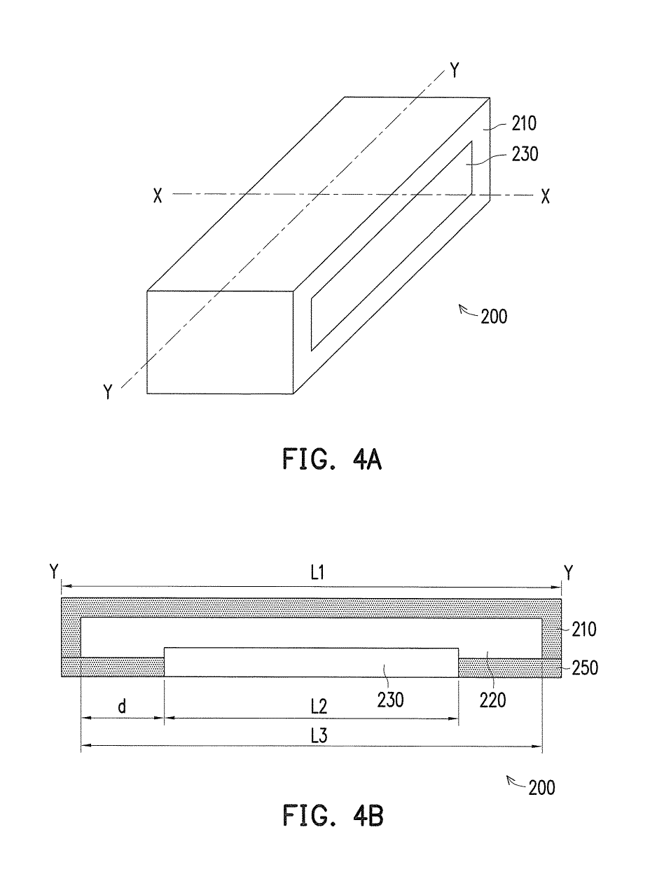

FIG. 4A is a schematic three-dimensional diagram illustrating the light emitting device package structure depicted in FIG. 3G. FIG. 4B is a schematic cross-sectional diagram taken along the line Y-Y depicted in FIG. 4A. With reference to FIG. 3G, FIG. 4A, and FIG. 4B, note that FIG. 3G is a schematic cross-sectional diagram taken along the line X-X depicted in FIG. 4A. In the present embodiment, the length D of the side surface 221 of the wavelength conversion layer 220 in each light emitting device package structure 200 is 0.22 mm, the total height H1 of the first protection element 210 and the second protection element 250 is 0.30 mm, and the width W of the first protection element 210 or the second protection element 250 is 0.80 mm, for instance. With reference to FIG. 4B, the total length L1 of the light emitting device package structure 200 is 2.17 mm, the length L2 of the light emitting device 230 is 1.27 mm, and the length L3 of the wavelength conversion layer 220 is 1.87 mm, for instance. A distance d is between an edge of the light emitting device 230 and an edge of the wavelength conversion layer 220, and d is 0.30 mm, for instance.

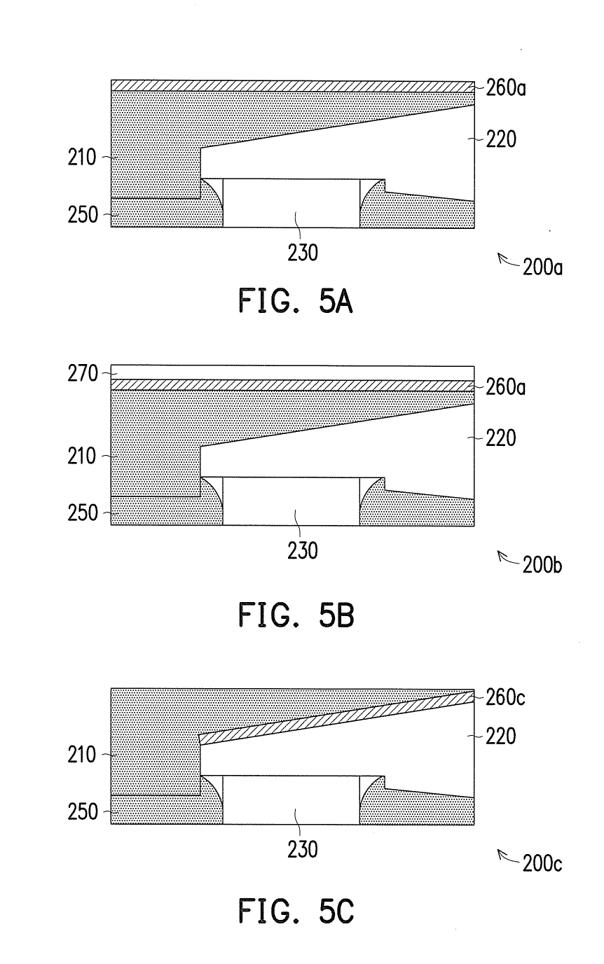

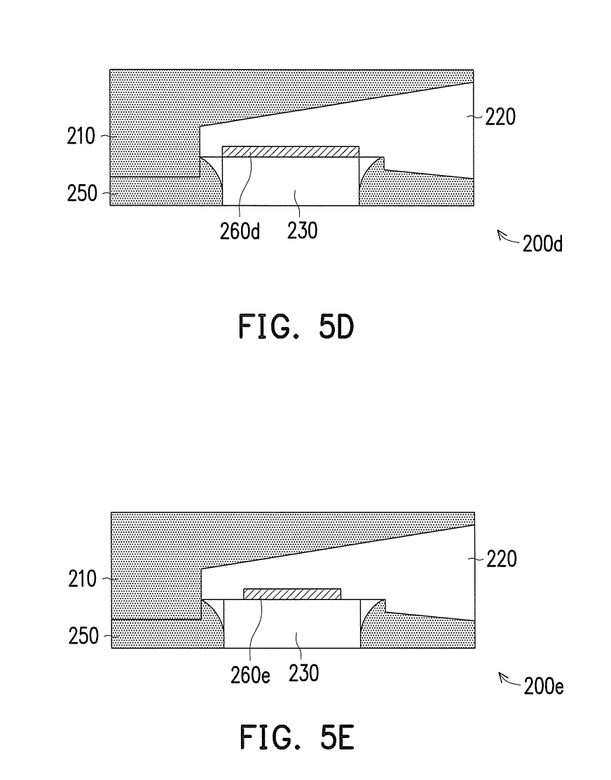

FIG. 5A to FIG. 5E are schematic cross-sectional diagrams illustrating a light emitting device package structure according to several embodiments of the disclosure. According to the present embodiment, the light emitting device package structure 200a′ provided in the present embodiment is similar to the light emitting device package structure 200 illustrated in FIG. 3G, and the difference therebetween is that the light emitting device package structure 200a further includes a distributed Bragg reflective layer 260a disposed on a side surface of the first protection element 210 relatively away from the wavelength conversion layer 220. As to the manufacturing process, the distributed Bragg reflective layer 260a may be formed on the side surface of the first protection element 210 relatively away from the wavelength conversion layer 220 after the second protection element 250 is formed and before the cutting process is performed. The material of the distributed Bragg reflective layer 260a is, for instance, a stacked layer containing SiO₂ and TiO₂ or a stacked layer containing SiO₂ and Ta₂O₅, and the distributed Bragg reflective layer 260a is configured to block the forward light of the light emitting device 230, better prevent the forward light from penetrating the first protection element 210, and further enhance the light utilization rate. The distributed Bragg reflective layer 260a can be replaced by other materials characterized by reflectivity.

With reference to FIG. 5B, the light emitting device package structure 200b provided in the present embodiment is similar to the light emitting device package structure 200a illustrated in FIG. 5A, and the difference therebetween is that the light emitting device package structure 200b further includes a reflective protection layer 270 disposed on the distributed Bragg reflective layer 260a. Here, the distributed Bragg reflective layer 260a is located between the first protection element 210 and the reflective protection layer 270. As to the manufacturing method, the reflective protection layer 270 may be formed on the distributed Bragg reflective layer 260a after the distributed Bragg reflective layer 260a is formed, such that the distributed Bragg reflective layer 260a is located between the first protection element 210 and the reflective protection layer 270. The material of the reflective protection layer 270 is aluminum, silicon, or SiO₂, and the reflective protection layer 270 is configured to protect the distributed Bragg reflective layer 260a.

It should be mentioned that the location of the distributed Bragg reflective layer 260a is not limited herein. In another embodiment of the disclosure, a distributed Bragg reflective layer 260c of a light emitting device package structure 200c as shown in FIG. 5C may be disposed on the inclined bottom 224 of the wavelength conversion layer 220 and covers the inclined bottom 224. As to the manufacturing method, the distributed Bragg reflective layer 260c may be formed in the first recesses C1′ after the first protection element 210 is formed and before the wavelength conversion material 220a is provided to fill the first recesses C1′ (as shown in FIG. 3A). Alternatively, as shown in FIG. 5D, a distributed Bragg reflective layer 260d of a light emitting device package structure 200d may be disposed on the upper surface 232 of the light emitting device 230 and may completely cover the upper surface 232; in another embodiment, as shown in FIG. 5E, a distributed Bragg reflective layer 260e of a light emitting device package structure 200e may be disposed on the upper surface 232 of the light emitting device 230 and may partially cover the upper surface 232. As to the manufacturing method, the distributed Bragg reflective layers 260d and 260e may be formed on the die bonding stages 222 of the wavelength conversion adhesive layers 220 after the wavelength conversion material 220a is provided to fill the first recesses C1′ (as shown in FIG. 3A) and before the light emitting devices 230 are placed on the wavelength conversion layers 220.

To sum up, the protection element of the light emitting device package structure encapsulates the side surface of the light emitting device and one side surface of the wavelength conversion layer, and the other side surface of the wavelength conversion layer is aligned with an side surface of the protection element. Thanks to the design of the protection element, the light emitted from the light emitting device can render reflective effects, and the wavelength conversion layer guides the light emitted from the light emitting device to exit from the lateral instead of exiting from the front. Thereby, the light emitting device package structure not only achieves favorable lateral light exiting effects but also has large light emitting area and favorable light emitting uniformity.

Although the disclosure has been provided with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

What is claimed is:

1. A light emitting device package structure comprising:
at least one light emitting device having an upper surface, a lower surface opposite to the upper surface, and a side surface connecting the upper surface and the lower surface;
a wavelength conversion layer disposed on the upper surface of the at least one light emitting device, the wavelength conversion layer having a first side surface and a second side surface opposite to each other;
a protection element encapsulating the side surface of the at least one light emitting device and the second side surface of the wavelength conversion layer and exposing the lower surface of the at least one light emitting device, wherein a third side surface of the protection element is aligned with the first side surface of the wavelength conversion layer.

2. The light emitting device package structure as recited in claim 1, wherein the wavelength conversion layer comprises a low concentration layer and a high concentration layer, the upper surface of the at least one light emitting device is in contact with the high concentration layer, the low concentration layer has the first side surface and the second side surface, the high concentration layer has a fourth side surface and a fifth side surface opposite to each other, and the fifth side surface of the high concentration layer is aligned with the second side surface of the low concentration layer.

3. The light emitting device package structure as recited in claim 2, wherein the protection element comprises a first protection element and a second protection element, the low concentration layer has a first surface and a second surface opposite to each other, the high concentration layer is disposed on the first surface of the low concentration layer, the second protection element encapsulates the side surface of the at least one light emitting device, the second side surface of the low concentration layer, and the fourth side surface and the fifth side surface of the high concentration layer, a top surface of the second protection element is aligned with the second surface of the low concentration layer, and the first protection element covers the second surface of the low concentration layer and the top surface of the second protection element.

4. The light emitting device package structure as recited in claim 1, wherein an area of the first side surface of the wavelength conversion layer is greater than an area of the second side surface of the wavelength conversion layer.

5. The light emitting device package structure as recited in claim 4, wherein the wavelength conversion layer has a die bonding stage and an inclined bottom opposite to the die bonding stage, the at least one light emitting device is located on the die bonding stage, and an acute angle is formed between the inclined bottom and the first side surface.

6. The light emitting device package structure as recited in claim 5, wherein the protection element comprises a first protection element and a second protection element, the first protection element encapsulates the wavelength conversion layer, and the second protection element encapsulates the side surface of the at least one light emitting device and covers the first protection element.

7. The light emitting device package structure as recited in claim 5, further comprising:
a distributed Bragg reflective layer disposed on a side surface of the first protection element relatively away from the wavelength conversion layer.

8. The light emitting device package structure as recited in claim 7, further comprising:
a reflective protection layer disposed on the distributed Bragg reflective layer, wherein the distributed Bragg reflective layer is located between the first protection element and the reflective protection layer.

9. The light emitting device package structure as recited in claim 1, the protection element further comprises a reflective curved surface, and the reflective curved surface surrounds the side surface of the at least one light emitting device and is in contact with the side.

10. The light emitting device package structure as recited in claim 1, further comprising:
a die bonding layer disposed between the side surface of the at least one light emitting device and the protection element.

11. The light emitting device package structure as recited in claim 1, wherein the number of the at least one light emitting device is plural, the light emitting devices are spaced from one another, and every two adjacent light emitting devices of the light emitting devices expose a portion of the wavelength conversion layer.

12. A light emitting device package structure comprising:
at least one light emitting device having an upper surface, a lower surface, and a side surface connecting the upper surface and the lower surface;
a wavelength conversion layer disposed on the upper surface of the at least one light emitting device, the wavelength conversion layer having a first side surface, a second side surface opposite to the first side surface, and a top surface connecting the first side surface and the second side surface; and
a protection element encapsulating the side surface of the at least one light emitting device, the second side surface of the wavelength conversion layer, and the top surface of the wavelength conversion layer, wherein a third side surface of the protection element is aligned with the first side surface of the wavelength conversion layer.

13. The light emitting device package structure as recited in claim 12, wherein an area of the first side surface of the wavelength conversion layer is greater than an area of the second side surface of the wavelength conversion layer.

14. The light emitting device package structure as recited in claim 12, wherein the wavelength conversion layer has a die bonding stage opposite to the top surface of the wavelength conversion layer, and the at least one light emitting device is located on the die bonding stage.

15. The light emitting device package structure as recited in claim 12, wherein the protection element comprises a first protection element and a second protection element, the first protection element encapsulates the side surface of the at least one light emitting device, and the second protection element encapsulates the wavelength conversion layer but exposes the first side surface of the wavelength conversion layer.

16. The light emitting device package structure as recited in claim 15, the first protection element further comprises a reflective curved surface, and the reflective curved surface surrounds the side surface of the at least one light emitting device and is in contact with the side.

17. A light emitting device package structure comprising:
at least one light emitting device having an upper surface, a lower surface, and a side surface connecting the upper surface and the lower surface;
a first protection element encapsulating the side surface of the at least one light emitting device;
a wavelength conversion layer disposed on the upper surface of the at least one light emitting device and a portion of the first protection element, the wavelength conversion layer having a first side surface, a second side surface opposite to the first side surface, and a top surface connecting the first side surface and the second side surface; and
a second protection element disposed on a portion of the first protection element, the second protection element at least encapsulating the second side surface and the top surface of the wavelength conversion layer, wherein the at least one light emitting device has a light exiting plane, and the light exiting plane comprises a portion of the first protection element, the wavelength conversion layer, and a portion of the second protection element.

18. The light emitting device package structure as recited in claim 17, wherein an area of the first side surface of the wavelength conversion layer is greater than an area of the second side surface of the wavelength conversion layer.

19. The light emitting device package structure as recited in claim 17, wherein the wavelength conversion layer has a die bonding stage opposite to the top surface of the wavelength conversion layer, and the at least one light emitting device is located on the die bonding stage.

20. The light emitting device package structure as recited in claim 17, wherein the first protection element further comprises a reflective curved surface, and the reflective curved surface surrounds the side surface of the at least one light emitting device and is in contact with the side surface.
